(19) United States
(12) Patent Application Publication
(10) Pub. No.: US 2023/0036650 A1
(43) Pub. Date: Feb. 2, 2023

(54) SENSE LINES FOR HIGH-SPEED APPLICATION PACKAGES

(71) Applicant: QUALCOMM Incorporated, San Diego, CA (US)

(72) Inventors: Yuan LI, Irvine, CA (US); Aniket PATIL, San Diego, CA (US); Hong Bok WE, San Diego, CA (US); Abdolreza LANGARI, San Diego, CA (US); Lisha ZHANG, San Diego, CA (US)

(21) Appl. No.: 17/386,278

(22) Filed: Jul. 27, 2021

(51) Int. Cl. H01L 23/60; H01L 21/50; H01L 23/522

(52) U.S. Cl. CPC H01L 23/60; H01L 21/50; H01L 23/5226

(57) ABSTRACT

In an aspect, a semiconductor includes a substrate. The substrate includes a column comprising a conductive paste that passes through a plurality of metal layers, a resin sheath surrounding the column, a ground shield surrounding the resin sheath, and a plurality of sense lines. The plurality of sense lines include a first sense line that is connected to the column comprising the conductive paste and a second sense line that is connected to the ground shield. The resin comprises a dielectric material.

### BACKGROUND OF THE DISCLOSURE

### 1. Field of the Disclosure

Aspects of this disclosure relate generally to an integrated circuit (IC), and particularly to sense lines in a semiconductor.

### 2. Description of the Related Art

In a semiconductor (also referred to as a chip or integrated circuit (IC)), internal connections known as sense lines may be used for sensing (e.g., testing). For example, the sense lines may connect to a Power Distribution Network (PDN), a power management IC (PMIC), or the like. Typically, 3 to 4 vias, having a size of about 100 micrometers (μm) each are used and 10 to 15 jumpers having a size of about 200 μm×200 μm may be used. Thus, the area occupied by the sense lines (including jumpers) may be about 400 μm×400 μm.

### SUMMARY

The following presents a simplified summary relating to one or more aspects disclosed herein. As such, the following summary should not be considered an extensive overview relating to all contemplated aspects, nor should the following summary be regarded to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In a first aspect, a semiconductor includes a substrate. The substrate includes a column comprising a conductive paste that passes through a plurality of metal layers, a resin sheath surrounding the column, a ground shield surrounding the resin sheath, and a plurality of sense lines. The plurality of sense lines include a first sense line that is connected to the column comprising the conductive paste and a second sense line that is connected to the ground shield. The resin sheath comprises a dielectric material.

In a second aspect, a method of fabricating a semiconductor device includes building up a substrate. Building up the substrate includes forming a column comprising a conductive paste that passes through a plurality of metal layers, forming a resin sheath that surrounds the column, forming a ground shield that surrounds the resin sheath, and forming a plurality of sense lines including a first sense line and a second sense line. The first sense line is connected to the column and the second sense line is connected to the ground shield. The resin sheath comprises a dielectric material.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof. A more complete understanding of the present disclosure may be obtained by reference to the following Detailed Description when taken in conjunction with the accompanying Drawings. In the figures, the left-most digit(s) of a reference number identifies the figure in which the reference number first appears. The same reference numbers in different figures indicate similar or identical items.

FIG. 1 illustrates a block diagram of an example package with a cored substrate, according to various aspects of the disclosure.

FIG. 2 illustrates a block diagram of an example package with a coreless substrate, according to various aspects of the disclosure.

FIGS. 3A, 3B, 3C, 3D, 3E, 3F, 3G, and 3H illustrate different stages in a fabrication process for an example package with a cored substrate, according to various aspects of the disclosure.

FIGS. 4A, 4B, 4C, 4D, 4E, 4F, 4G, and 4H illustrate different stages in a fabrication process for an example package with a cored substrate, according to various aspects of the disclosure.

FIG. 5 illustrates an example process that includes forming a column comprising a conductive paste, according to aspects of the disclosure.

FIG. 6 illustrates an example process that includes depositing a conductive paste into a hole in portion of a substrate, according to aspects of the disclosure.

FIG. 7 illustrates an example mobile device in accordance with one or more aspects of the disclosure.

FIG. 8 illustrates various electronic devices that may be integrated with an integrated device or a semiconductor device in accordance with one or more aspects of the disclosure.

### DETAILED DESCRIPTION

Disclosed are systems and techniques to reduce an amount of space in a semiconductor package (“package”) used by sense lines. A conductive paste may be used to create a cylindrical shaped sense line (e.g., for a power rail), with an outer shield around the sense line that acts as a ground. The sense line structure described herein occupies a space of about 250 μm×250 μm, as compared to a conventional sense lines structure that occupies 400 μm×400 μm, resulting in space savings of about 50% in the package.

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “example” and/or “example” are used herein to mean “serving as an example, instance, or illustration.” Any aspect described herein as “example” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

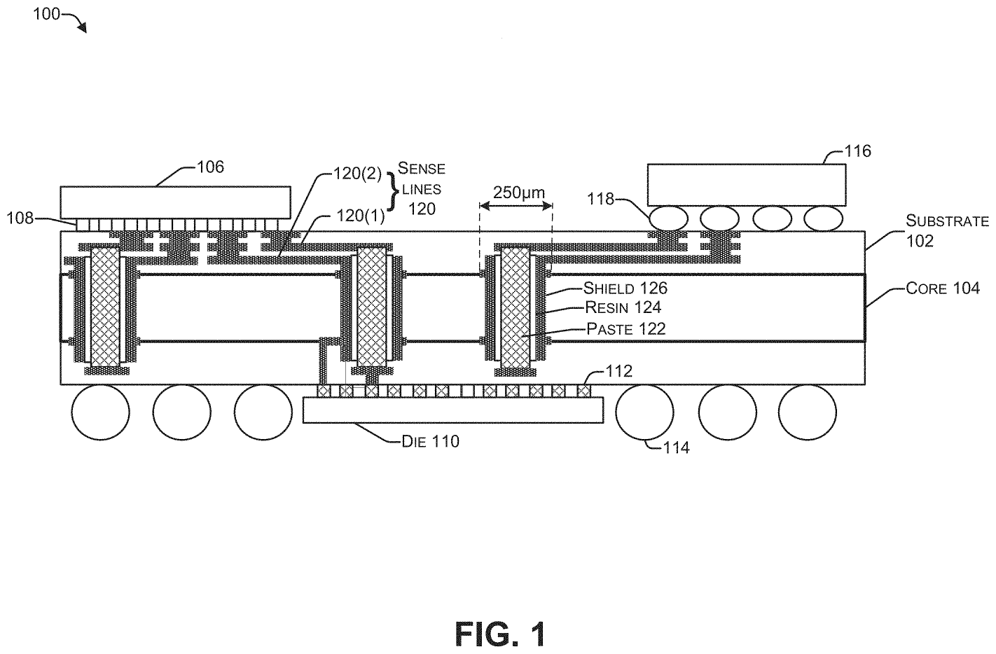

FIG. 1 illustrates a block diagram of an example package 100 with a cored substrate 102, according to various aspects of the disclosure. The cored substrate 102 includes a core 104. An active device 106, such as a Power Management Integrated Circuit (PMIC), is electrically coupled to a top portion of the cored substrate 102 using an interconnect 108, such as pins, balls, bumps, or the like. A die 110, such as an application processor (AP) die, is electrically coupled to a bottom portion of the cored substrate 102 using an interconnect 112, such as pins, balls, bumps, or the like. The bottom surface of the cored substrate 102 may include an interconnect 114, such as balls, pins, or the like, to enable the package 100 to be attached to a printed circuit board (PCB) or the like. It will be appreciated that one or more additional dies 116 may be attached to the substrate 102 using an interconnect 118, such as pins, balls, bumps, or the like. Further, it will be appreciated that the location of die 116 may be on either side of the cored substrate 102. Accordingly, the various aspects disclosed herein should not be construed to be limited by the illustrated example configurations.

The substrate 102 includes one or more sense lines 120. For example, a sense line 120(1) may be connected to a column of conductive paste 122. While other materials such as copper, silver, or the like can be used, the conductive paste 122 provides a lower cost option to achieve electrical connectivity. The conductive paste 122 may be insulated by being surrounded by resin sheath 124. A ground shield 126 surrounds the resin sheath 124 and, in some aspects, may be coupled to ground that is attached to a sense line 120(2). For illustration purposes, the sense lines 120 are shown as being coupled to ground. However, it should be understood that the sense lines 120 described herein may be used in other ways, such as to carry power, to carry a signal, or the like. Thus, the sense lines 120(1), 120(2) work together, with the sense line 120(1) carrying a signal (or power) to the conductive paste 122 and the sense line 120(2) connect to the ground shield 126. For example, the sense lines 120(1), 120(2), may be used as low current sense lines for monitoring the voltage on a power rail in a portion of the substrate 102.

The entire structure that includes the conductive paste 122, the resin sheath 124, and the ground shield 126 may have a width of about 250 micrometers (μm). Various example dimensions are provided herein as an aid to explaining the various aspects disclosed. It will be appreciated that these the various aspects disclosed are not limited to these example dimensions.

The ground shield 126 may be used as part of the ground sense return line (e.g., 120(2)) on one or more layers of multiple layers in the substrate 102. The ground shield 126 may formed from copper, silver, solder, or any other suitable highly conductive material. It will be appreciated that in some aspects the ground shield 126 can act as a ground shield surrounding the sense line that passes through the conductive paste 122. The conductive paste 122 may be added to the substrate using inkjet printing (or another means of extruding the conductive paste) and cured. The conductive paste 122 may comprise copper, silver, solder, or any other suitable highly conductive material.

The technical advantages of the sense lines described herein include occupying less space, e.g., about 250 μm×250 μm as compared to conventional sense lines that occupy about 400×400 μm. By taking up less space in the package 100, the package 100 can be shrunk or additional functionality can be added to the package 100. For example, the space savings may be used to increase an area available for routing on the package 100, reducing a size of a substrate, improving a layout of the package 100, improving power delivery network (PDN) connectivity, and the like.

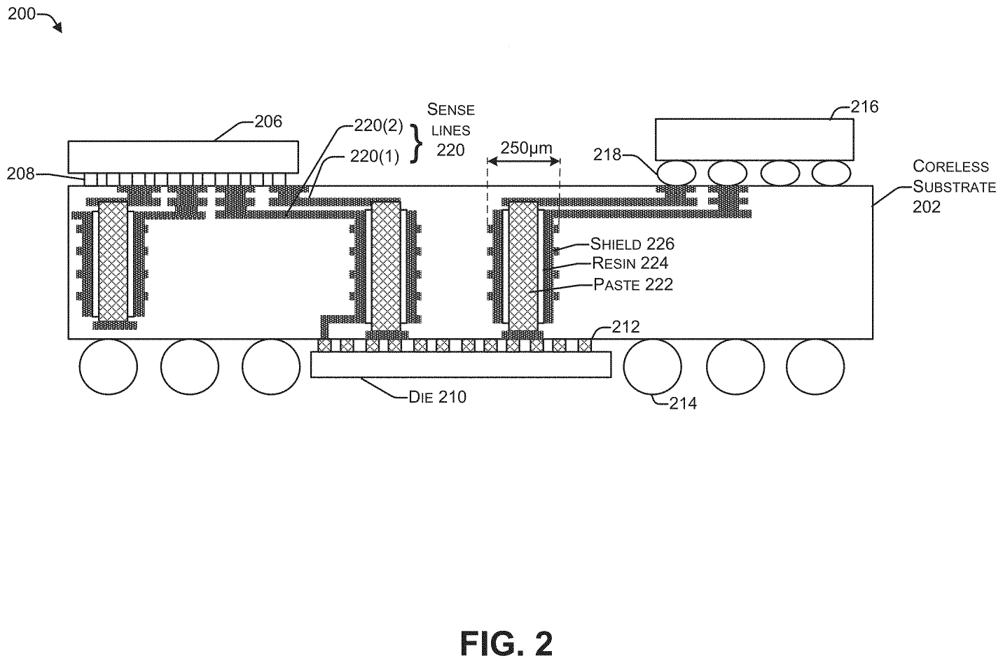

FIG. 2 illustrates a block diagram of an example package 200 with a coreless substrate 202, according to various aspects of the disclosure. An active device 206 (e.g., a PMIC) is electrically coupled to a top portion of the coreless substrate 202 using an interconnect 208, such as pins, balls, bumps, or the like. A die 210 (e.g., AP die) is electrically coupled to a bottom portion of the substrate 102 using an interconnect 212, such as pins, balls, bumps, or the like. The bottom surface of the coreless substrate 202 may include an interconnect 214, such as balls, pins, or the like, to enable the package 200 to be attached to a Printed Circuit Board (PCB) or the like. Similar to the foregoing illustration, a die 216 (or multiple dies) may be attached to the coreless substrate 202 using the interconnect 218, such as pins, balls, bumps, or the like.

The coreless substrate 202 includes one or more sense lines 220. For example, the sense line 220(1) may be connected to a column of conductive paste 222. The conductive paste 222 may be insulated by being surrounded by resin sheath 224. A conductive ground shield 226 that surrounds the resin sheath 224 may be used as the ground that is attached to the sense line 220(2). Thus, the sense lines 220(1), 220(2) work together, with the sense line 220(1) carrying a signal (or power) to the conductive paste 222 and the sense line 220(2) connect to the ground shield 226. For example, the sense lines 220(1), 220(2), may be used as low current sense lines for a power rail. It should be understood that the sense lines 220 described herein may be used in many different ways, such as to connect to ground, to carry power, to carry a signal, or the like.

The ground shield 226 may be used as a ground sense return line on one or more layers of multiple layers in the coreless substrate 202. The entire structure that includes the conductive paste 222, the resin sheath 224, and the ground shield 226 may have a width of about 250 micrometers (μm). The conductive paste 222 may be added to the substrate using inkjet printing (or another means of extruding the conductive paste) and cured.

The technical advantages of the sense lines described herein include occupying less space, e.g., about 250 μm×250 μm as compared to conventional sense lines that occupy about 400 μm×400 μm. By taking up less space in the package 200, the package 200 can be shrunk or additional functionality can be added to the package 200. For example, the space savings may be used to increase an area available for routing on the package 200, reducing a size of a substrate, improving a layout of the package 200, improving power delivery network (PDN) connectivity, and the like.

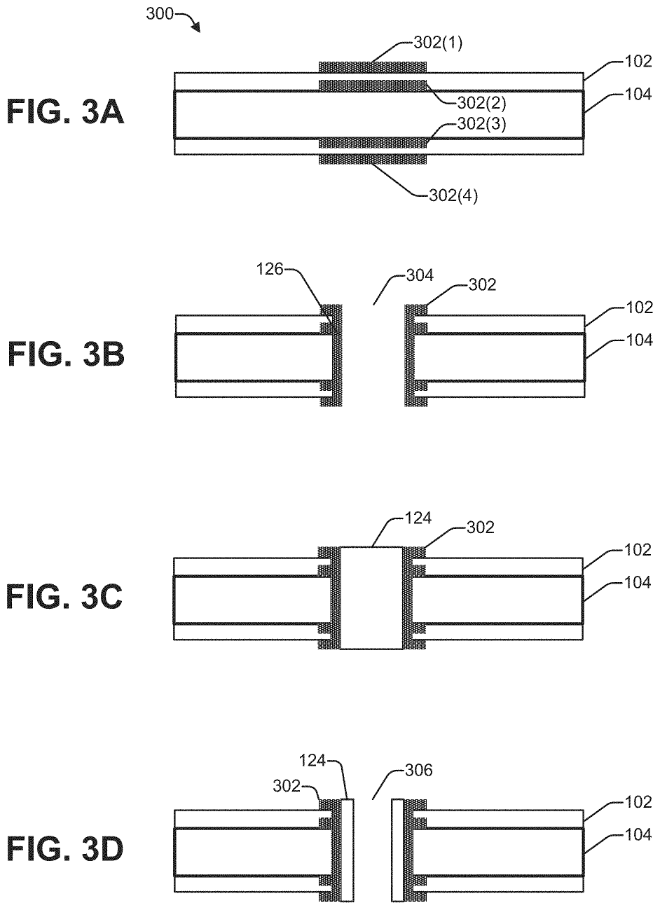

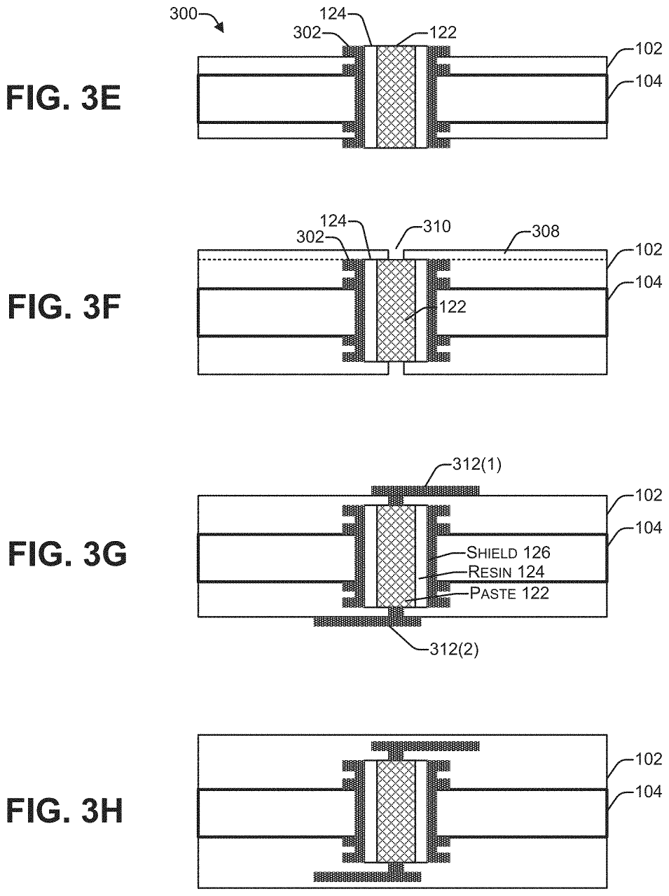

FIGS. 3A, 3B, 3C, 3D, 3E, 3F, 3G, and 3H illustrate different stages in an example fabrication of a package 300 that is similar to the package 100 of FIG. 1 that includes the cored substrate 102. To illustrate the various aspects of disclosure, example methods of fabrication are presented. Other methods of fabrication are possible and the discussed fabrication processes are presented only to aid understanding of the concepts disclosed herein and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

FIG. 3A illustrates a portion of a fabrication process for the package 300 with cored substrate, similar to the package 100 of FIG. 1, according to various aspects of the disclosure. The package 300 is formed, in some aspects, using a process to build-up the substrate 102 over the core 104. Multiple pads, such as representative pads 302(1), 302(2), 302(3), 302(4), may be used for via pads on multiple layers (e.g., metal 1, metal 2, metal 3, metal 4, and the like). A diameter of the pads 302 may be about 250 μm. For ease of understanding, other routing structures are not illustrated in FIG. 3A. Multiple layers are built based on where the sense lines start and stop. The sense lines may be added approximately symmetric around the core 104. Additional layers may be added after creating the sense lines.

FIG. 3B illustrates a further portion of a fabrication process for the package 300, according to various aspects of the disclosure. A drill (e.g., a mechanical drill, a laser, or another type of hole creating apparatus) may be used to create a hole 304 and form an outer ring of the sense lines (e.g., the pads 302 of FIG. 3A), as illustrated in FIG. 3B. The hole 304 may be between about 150-200 μm in diameter. Plating the hole (PTH) may be performed to form the ground shield 126. In some aspects, the sheath may be formed from a thickness of a Copper (Cu) plating of about 10 μm. For example, a 150-350 μm via may be used with 10 um Cu plating for connecting to the ground shield 126. The sheath may be placed on the plated Cu to avoid a short with 124 and 126.

FIG. 3C illustrates a further portion of a fabrication process for the package 300, according to various aspects of the disclosure. The hole 304 is filled with the resin sheath 124 (e.g., dielectric material). A dielectric constant (Dk) of the resin sheath 124 need not be taken into account when selecting the resin sheath 124 because sense signals that travel across the sense lines 120 of FIG. 1 and FIG. 2 are not high-speed signals. Thus, a relatively inexpensive resin sheath 124 can be used (e.g., to provide cost savings).

FIG. 3D illustrates a further portion of a fabrication process for the package 300, according to various aspects of the disclosure. A drill (e.g., a mechanical drill, a laser, or another type of hole creating apparatus) may be used to create a hole 306 having a diameter of approximately 100 μm.

FIG. 3E illustrates a further portion of a fabrication process for the package 300, according to various aspects of the disclosure. The hole 306 of FIG. 3D is filled with the conductive paste 122 and cured. For example, an inkjet printer or another type of means may be used to add the conductive paste 122 into the hole 306. A flash lamp or another type of curing means may be used to cure (e.g., harden) the conductive paste 122.

FIG. 3F illustrates a further portion of a fabrication process for the package 300, according to various aspects of the disclosure. The substrate 102 is further built-up by adding a dielectric layer 308. Vias, such as a representative via 310, are created using a laser, an etch, or the like.

FIG. 3G illustrates a further portion of a fabrication process for the package 300, according to various aspects of the disclosure. Metal layers, such as layers 312(1), 312(2), are built-up and additional steps in a manufacturing process for the substrate 102 may be performed.

FIG. 3H illustrates a further portion of a fabrication process for the package 300, according to various aspects of the disclosure. FIG. 3H illustrates a view of the completed package 300 including the ground shield 126, resin sheath 124 and conductive paste 122, similar to package 100.

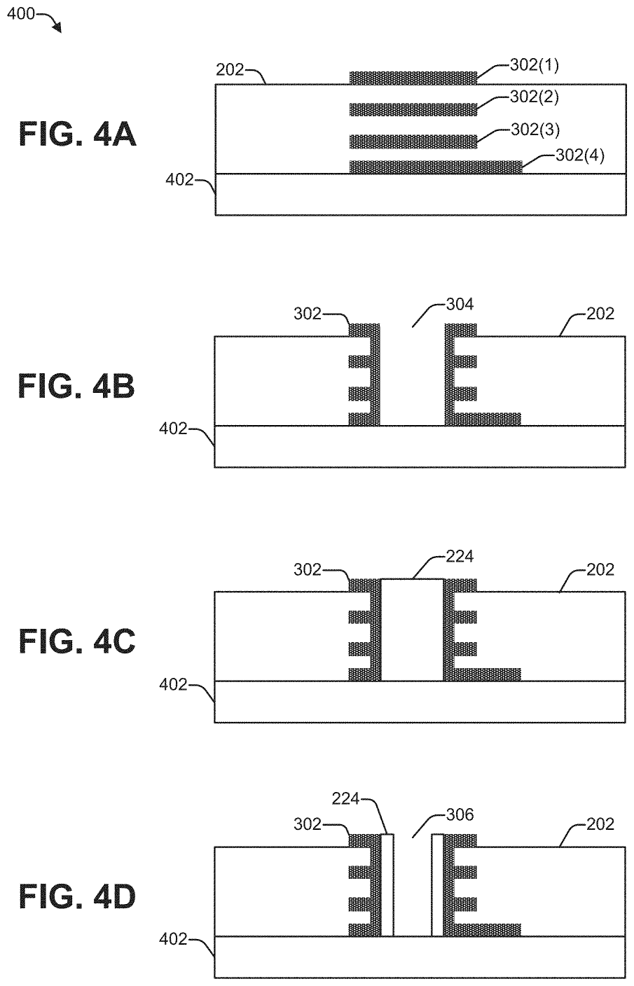

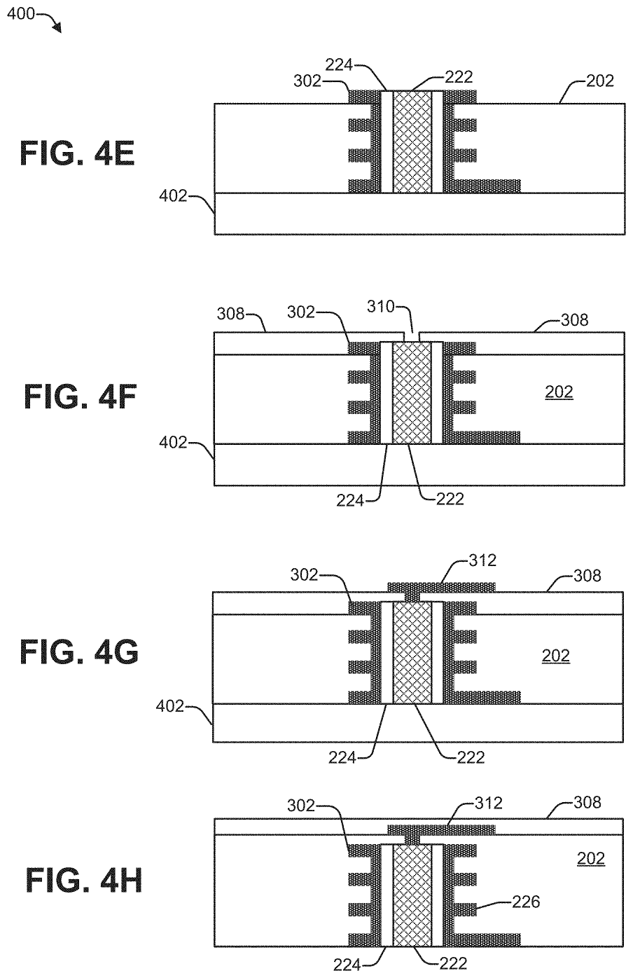

FIGS. 4A, 4B, 4C, 4D, 4E, 4F, 4G, and 4H illustrate different stages in an example fabrication of a package 400 that is similar to the package 400 of FIG. 4 that includes the coreless substrate 202. To illustrate the various aspects of disclosure, example methods of fabrication are presented. Other methods of fabrication are possible and the discussed fabrication processes are presented only to aid understanding of the concepts disclosed herein and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

FIG. 4A illustrates a portion of a fabrication process for the package 400 with cored substrate, similar to the package 200 of FIG. 2, according to various aspects of the disclosure. The package 400 is formed, in some aspects, using a carrier substrate 402 and the coreless substrate 202. The coreless substrate 202 may, in some aspects, be an Embedded Trace Substrate (ETS). Multiple pads, such as representative pads 302(1), 302(2), 302(3), 302(4), may be used for via pads on multiple layers (e.g., metal 1, metal 2, metal 3, metal 4, and the like). A diameter of the pads 302 may be about 250 μm. For ease of understanding, other routing structures are not illustrated in FIG. 4A. Multiple layers are built based on where the sense lines start and stop. The sense lines may be added approximately symmetric around the coreless substrate 202. Additional layers may be added after creating the sense lines.

FIG. 4B illustrates a further portion of a fabrication process for the package 400, according to various aspects of the disclosure. A drill (e.g., a mechanical drill, a laser, or another type of hole creating apparatus) may be used to create a hole 304 and form an outer ring of the sense lines (e.g., the pads 302 of FIG. 4A), as illustrated in FIG. 4B. The hole 304 may be between about 150-200 μm in diameter. Plating the hole (PTH) may be performed to form the ground shield 226. In some aspects, the ground shield 226 may be formed from a thickness of a Copper (Cu) plating of about 10 μm. For example, a 150-350 μm via may be used with 10 um Cu plating for connecting to the ground shield 126. The sheath may be placed on the plated Cu to avoid a short with 124 and 126.

FIG. 4C illustrates a further portion of a fabrication process for the package 400, according to various aspects of the disclosure. The hole 304 of FIG. 4B is filled with the resin sheath 224 (e.g., dielectric material). A dielectric constant (Dk) of the resin sheath 224 need not be taken into account when selecting the resin sheath 224 because sense signals that travel across the sense lines 220 are not high-speed signals. Thus, resin sheath 224, which is relatively inexpensive, can be used to provide cost savings.

FIG. 4D illustrates a further portion of a fabrication process for the package 400, according to various aspects of the disclosure. A drill (e.g., a mechanical drill, a laser, or another type of hole creating apparatus) may be used to create a hole 306. In some aspects, the hole 306 may have a diameter of approximately 100 μm.

FIG. 4E illustrates a further portion of a fabrication process for the package 400, according to various aspects of the disclosure. The hole 306 of FIG. 4D is filled with the conductive paste 222 and cured. For example, an inkjet printer or another type of means may be used to add the conductive paste 222 into the hole 306. A flash lamp or another type of curing means may be used to cure (e.g., harden) the conductive paste 222.

FIG. 4F illustrates a further portion of a fabrication process for the package 400, according to various aspects of the disclosure. The coreless substrate 202 is further built-up by adding the dielectric layer 308. Vias, such as a representative via 310, are created using a laser, an etch, or the like.

FIG. 4G illustrates a further portion of a fabrication process for the package 400, according to various aspects of the disclosure. Metal layers, such as representative metal layer 312, are built-up and additional steps in a manufacturing process for the coreless substrate 202 (e.g., ETS) may be performed.

FIG. 4H illustrates a further portion of a fabrication process for the package 400, according to various aspects of the disclosure. The carrier substrate 402 may be removed to form the completed package 400, illustrated in FIG. 4H.

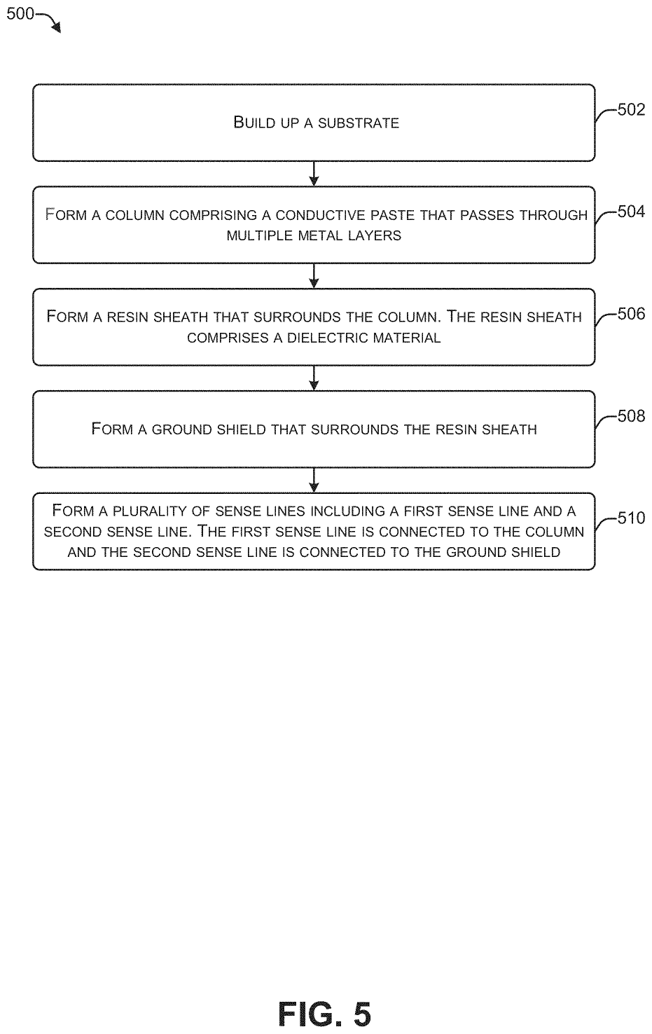

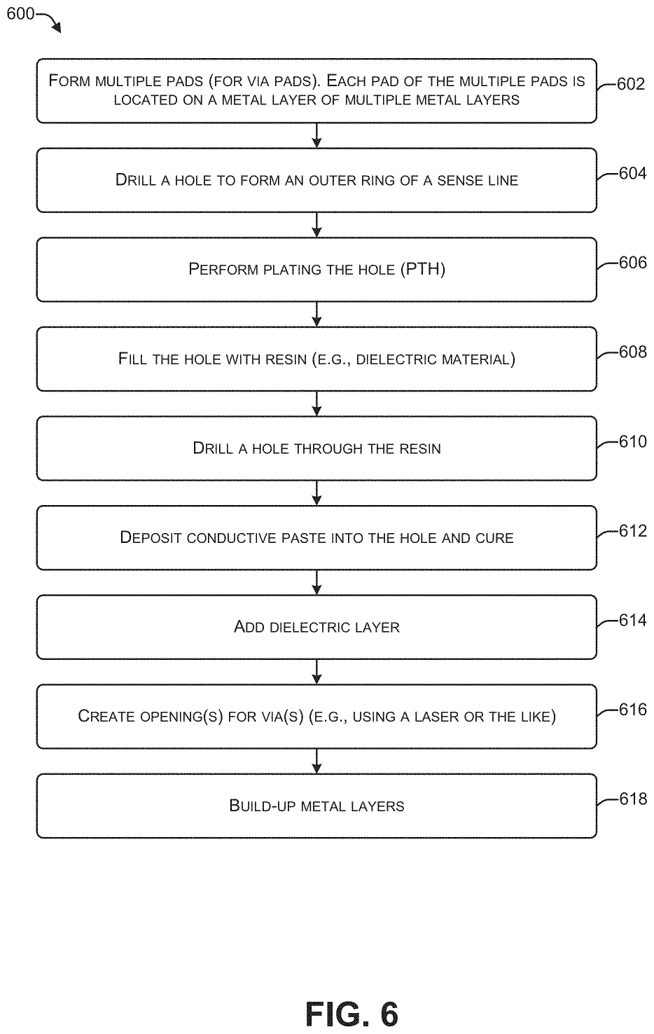

In the flow diagrams of FIGS. 5 and 6, each block represents one or more operations that can be implemented in hardware, software, or a combination thereof. In the context of software, the blocks represent computer-executable instructions that, when executed by one or more processors, cause the processors to perform the recited operations. Generally, computer-executable instructions include routines, programs, objects, modules, components, data structures, and the like that perform particular functions or implement particular abstract data types. The order in which the blocks are described is not intended to be construed as a limitation, and any number of the described operations can be combined in any order and/or in parallel to implement the processes. For discussion purposes, the processes 500 and 600 are described with reference to FIGS. 1, 2, 3A-3H, and 4A-4H as described above, although other models, frameworks, systems and environments may be used to implement these processes.

FIG. 5 illustrates an example process that includes forming a column comprising a conductive paste, according to aspects of the disclosure. The process 500 may be performed as part of a semiconductor manufacturing process.

At 502, the process 500 builds up a substrate. For example, FIGS. 3A-3H illustrate building up a cored substrate and FIGS. 4A-4H illustrate building up a coreless substrate.

At 504, the process 500 forms a column comprising a conductive paste that passes through multiple metal layers. For example, in FIGS. 3E and 4E, the conductive paste 122 is deposited into the hole 306 and cured.

At 506, the process 500 forms of the resin sheath that surrounds the column. The resin sheet comprises a dielectric material. For example, in FIGS. 3C and 4C, the resin sheath 124 is deposited into the hole 304 and FIGS. 3D and 4D and the hole 306 is created in the resin to form the resin sheath 124.

At 508, the process 500 forms a ground shield that surrounds the resin sheath. For example, in FIGS. 3A and 3B, the pads 302 may be added, with each pad 302 at a corresponding metal layer. The hole 304 may be created to create the ground shield 126.

At 510, the process 500 forms a plurality of sense lines including a first sense line and a second sense line. The first line sense line is connected to the column and the second sense line is connected to the ground shield. For example, in FIGS. 1 and 2, the sense lines 120 may be created, with sense line 120(1) connected to the conductive paste 122 and the sense line 120(2) connected to the ground shield 126.

The technical advantages of using the process 500 to create the sense lines described herein include creating sense lines that occupy less space, e.g., about 250 μm×250 μm as compared to conventional sense lines that occupy about 400 μm×400 μm. The process 500 can be applied to both cored substrates (e.g., as illustrated in FIG. 1) and coreless substrates (e.g., as illustrated in FIG. 2). By taking up less space in a package (e.g., the package 100, 200), the package can be shrunk or additional functionality can be added.

FIG. 6 illustrates an example process 600 that includes depositing a conductive paste into a hole in portion of a substrate, according to aspects of the disclosure. The process 600 may be performed as part of a semiconductor manufacturing process.

At 602, the process 600 forms multiple pads (e.g., for via pads). Each pad of the multiple pads is located on a corresponding metal layer of multiple metal layers. For example, in FIGS. 3A and 4A, multiple pads, such as representative pads 302(1), 302(2), 302(3), 302(4), may be formed. The multiple pads may be used for via pads on multiple layers (e.g., metal 1, metal 2, metal 3, metal 4, and the like).

At 604, the process 600 drills a hole to form an outer ring of a sense line. For example, in FIGS. 3B and 4B, a drill (e.g., a mechanical drill, a laser, or another type of hole creating apparatus) may be used to create the hole 304 and form an outer ring of the sense lines (e.g., the pads 302 of FIG. 3A, 4A), as illustrated in FIG. 4A, 4B.

At 606, the process 600 performs a plate the hole (PTH). For example, in FIGS. 3B and 4B, a PTH may be performed using Copper (Cu) or another type of metal (or metal alloy). For example, the Cu plating may have a thickness of about 10 μm.

At 608, the process 600 fills the hole with resin (e.g., a dielectric material). For example, in FIGS. 3C and 4C, the hole 304 (of FIG. 3B, 4B) is filled with the resin sheath 124 (e.g., dielectric material).

At 610, the process 600 drills a hole through the resin. For example, in FIGS. 3D and 4D, a drill (e.g., a mechanical drill, a laser, or another type of hole creating apparatus) may be used to create the hole 306. The hole 306 may, in some aspects, have a diameter of approximately 100 μm.

At 612, the process 600 deposits a conductive paste into the hall and cures the conductive paste. For example, in FIGS. 3E and 4E, the hole 306 of FIG. 3D, 4D is filled with the conductive paste 122 and cured. An inkjet printer or another type of depositing means may be used to deposit the conductive paste 122 into the hole 306. A flash lamp or another type of curing means may be used to cure (e.g., harden) the conductive paste 122.

At 614, the process 600 adds a dielectric layer. For example, in FIGS. 3F and 4F, the substrate 102 and the coreless substrate 202 are further built-up by adding the dielectric layer 308.

At 616, the process 600 creates one or more openings for vias (e.g., using a laser, an etch, or another type of means). For example, in FIGS. 3F and 4F, vias, such as a representative via 310, are created (e.g., using a laser, an etch, or the like) in the dielectric layer 308.

At 618, the process 600 builds up the multiple metal layers. For example, in FIGS. 3G and 4G, metal layers, such as representative metal layer 312, are built-up and additional steps in a manufacturing process are performed for the substrates 102, 202.

The technical advantages of using the process 600 to create the sense lines described herein include creating sense lines that occupy less space, e.g., about 250 μm×250 μm as compared to conventional sense lines that occupy about 400 μm×400 μm. The process 600 can be applied, with minimal modification, to both cored substrates (e.g., as illustrated in FIG. 1) and coreless substrates (e.g., as illustrated in FIG. 2). By taking up less space in a package (e.g., the package 100, 200), the package can be shrunk or additional functionality can be added.

It will be appreciated that the foregoing fabrication process was provided merely as general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

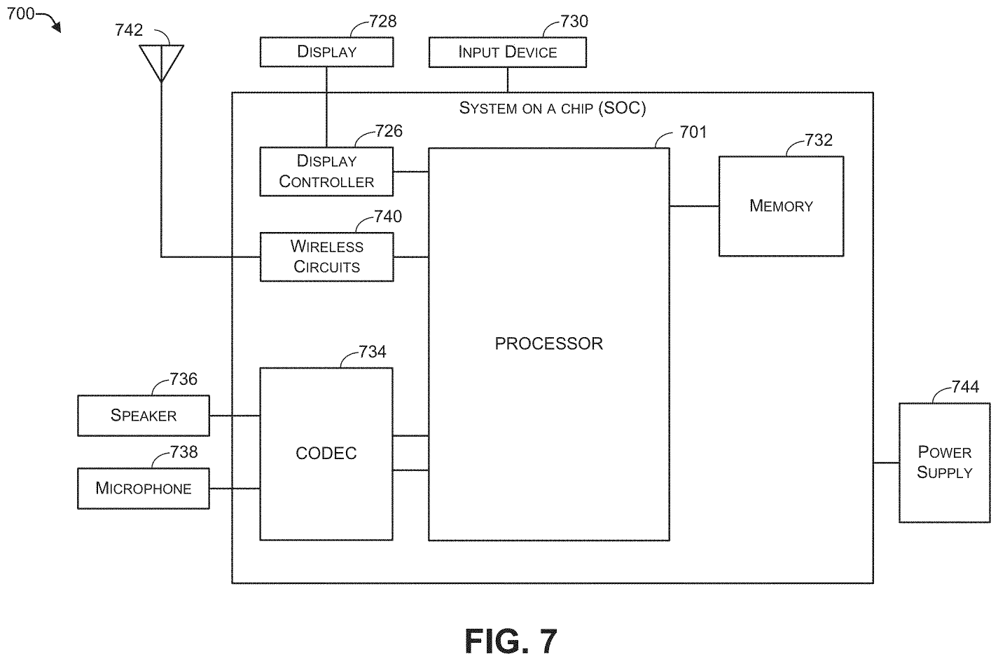

FIG. 7 illustrates an example mobile device 700 in accordance with some examples of the disclosure. Referring now to FIG. 7, a block diagram of a mobile device that is configured according to example aspects is depicted and generally designated mobile device 700. In some aspects, mobile device 700 may be configured as a wireless communication device. As shown, mobile device 700 includes processor 701. Processor 701 may be communicatively coupled to memory 732 over a link, which may be a die-to-die or chip-to-chip link. Processor 701 is a hardware device capable of executing logic instructions. Mobile device 700 also includes display 728 and display controller 726, with display controller 726 coupled to processor 701 and to display 728.

In some aspects, FIG. 7 may include coder/decoder (CODEC) 734 (e.g., an audio and/or voice CODEC) coupled to processor 701; speaker 736 and microphone 738 coupled to CODEC 734; and wireless circuits 740 (which may include a modem, RF circuitry, filters, etc., any of which may be implemented using the package 100 or the package 200 as described herein) coupled to wireless antenna 742 and to processor 701.

In a particular aspect, where one or more of the above-mentioned blocks are present, processor 701, display controller 726, memory 732, CODEC 734, and wireless circuits 740 can include the package 100 or package 200 which may be implemented in whole or part using the techniques disclosed herein. Input device 730 (e.g., physical or virtual keyboard), power supply 744 (e.g., battery), display 728, input device 730, speaker 736, microphone 738, wireless antenna 742, and power supply 744 may be external to the mobile device 700 and may be coupled to a component of mobile device 700, such as an interface or a controller.

It should be noted that although FIG. 7 depicts a mobile device 700, processor 701 and memory 732 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

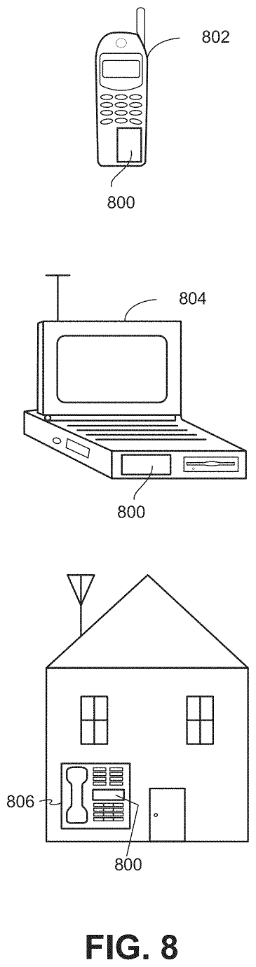

FIG. 8 illustrates various electronic devices that may be integrated with any of the aforementioned integrated device, semiconductor device, or package in accordance with various examples of the disclosure. For example, a mobile phone device 802, a laptop computer device 804, and a fixed location terminal device 806 may each be considered generally user equipment (UE) and may include a semiconductor 800 (e.g., including either the package 100 or the package 200). The semiconductor 800 may be, for example, be included in any of the integrated circuits, dies, integrated devices, integrated device packages, integrated circuit devices, device packages, integrated circuit (IC) packages, package-on-package devices described herein. The devices 802, 804, 806 illustrated in FIG. 8 are merely examples. Other electronic devices may also feature the semiconductor 800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, base stations, access points, routers, electronic devices implemented in automotive vehicles (e.g., autonomous vehicles), an Internet of things (IoT) device or any other device that stores or retrieves data or computer instructions or any combination thereof.

It can be noted that, although particular frequencies, integrated circuits (ICs), hardware, and other features are described in the aspects herein, alternative aspects may vary. That is, alternative aspects may utilize additional or alternative frequencies (e.g., other the 60 GHz and/or 28 GHz frequency bands), antenna elements (e.g., having different size/shape of antenna element arrays), scanning periods (including both static and dynamic scanning periods), electronic devices (e.g., WLAN APs, cellular base stations, smart speakers, IoT devices, mobile phones, tablets, personal computer (PC), etc.), and/or other features. A person of ordinary skill in the art will appreciate such variations.

It should be understood that any reference to an element herein using a designation such as “first,” “second,” and so forth does not generally limit the quantity or order of those elements. Rather, these designations may be used herein as a convenient method of distinguishing between two or more elements or instances of an element. Thus, a reference to first and second elements does not mean that only two elements may be employed there or that the first element must precede the second element in some manner. Also, unless stated otherwise a set of elements may comprise one or more elements. In addition, terminology of the form “at least one of A, B, or C” or “one or more of A, B, or C” or “at least one of the group consisting of A, B, and C” used in the description or the claims means “A or B or C or any combination of these elements.” For example, this terminology may include A, or B, or C, or A and B, or A and C, or A and B and C, or 2A, or 2B, or 2C, and so on.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. UEs can be embodied by any of a number of types of devices including but not limited to printed circuit (PC) cards, compact flash devices, external or internal modems, wireless or wireline phones, smartphones, tablets, consumer tracking devices, asset tags, and so on.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

One or more of the components, processes, features, and/or functions illustrated in FIGS. 1-8 may be rearranged and/or combined into a single component, process, feature or function or incorporated in several components, processes, or functions. Additional elements, components, processes, and/or functions may also be added without departing from the disclosure. It should also be noted that FIGS. 1-8 and corresponding description in the present disclosure are not limited to dies and/or ICs. In some implementations, FIGS. 1-8 and the corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a system in package (SiP), a system on chip (SoC), a package on package (PoP) device, and the like.

The foregoing disclosed devices and functionalities may be designed and configured into computer files (e.g., register-transfer level (RTL), Geometric Data Stream (GDS) Gerber, and the like) stored on computer-readable media. Some or all such files may be provided to fabrication handlers who fabricate devices based on such files. Resulting products may include semiconductor wafers that are then cut into semiconductor die and packaged into semiconductor packages, integrated devices, system-on-chip devices and the like, which may then be employed in the various devices described herein.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an insulator and a conductor). Furthermore, it is also intended that aspects of a clause can be included in any other independent clause, even if the clause is not directly dependent on the independent clause. Implementation examples are described in the following numbered clauses:

Clause 1. An apparatus comprising: a semiconductor device having a substrate comprising: a column comprising a conductive paste that passes through multiple metal layers; a resin sheath surrounding the column, wherein the resin sheath comprises a dielectric material; a ground shield surrounding the resin sheath; and a plurality of sense lines including a first sense line and a second sense line, wherein the first sense line is connected to the column and the second sense line is connected to the ground shield.

Clause 2. The apparatus of clause 1, wherein the substrate comprises a cored substrate.
Clause 3. The apparatus of any of clauses 1 to 2, wherein the substrate comprises a coreless substrate.
Clause 4. The apparatus of any of clauses 1 to 3, wherein at least a portion of the sense lines are coupled to a Power Management Integrated Circuit (PMIC).
Clause 5. The apparatus of any of clauses 1 to 4, wherein the column comprising the conductive paste has a diameter of about 100 micrometers.
Clause 6. The apparatus of any of clauses 1 to 5, wherein the column, the resin sheath, and the ground shield combined occupy an area of about 250 micrometers by about 250 micrometers.
Clause 7. The apparatus of any of clauses 1 to 6, further comprising: a die coupled to the semiconductor device.
Clause 8. The apparatus of any of clauses 1 to 7, wherein the apparatus is selected from the group consisting of: a music player, a video player, an entertainment unit, a navigation device, a communications device, a mobile device, a mobile phone, a smartphone, a personal digital assistant, an access point, a fixed location terminal, a tablet computer, a computer, a wearable device, an Internet of things (IoT) device, a laptop computer, a server, a base station, and a device in an automotive vehicle.
Clause 9. A method of fabricating a semiconductor device, the method comprising: building up a substrate comprising: forming a column comprising a conductive paste that passes through a plurality of metal layers; forming a resin sheath that surrounds the column, wherein the resin sheath comprises a dielectric material; forming a ground shield that surrounds the resin sheath; and forming a plurality of sense lines including a first sense line and a second sense line, wherein the first sense line is connected to the column and the second sense line is connected to the ground shield.
Clause 10. The method of clause 9, wherein the substrate comprises a cored substrate.
Clause 11. The method of any of clauses 9 to 10, wherein the substrate comprises a coreless substrate.
Clause 12. The method of any of clauses 9 to 11, wherein at least a portion of the sense lines are coupled to a Power Management Integrated Circuit (PMIC).
Clause 13. The method of any of clauses 9 to 12, wherein the column comprising the conductive paste has a diameter of about 100 micrometers.
Clause 14. The method of any of clauses 9 to 13, wherein the column, the resin sheath, and the ground shield combined occupy an area of about 250 micrometers by about 250 micrometers.
Clause 15. The method of any of clauses 9 to 14, further comprising: coupling a die to the semiconductor device.
Clause 16. The method of any of clauses 9 to 15, further comprising including the semiconductor device in an apparatus that is selected from the group consisting of: a music player, a video player, an entertainment unit, a navigation device, a communications device, a mobile device, a mobile phone, a smartphone, a personal digital assistant, an access point, a fixed location terminal, a tablet computer, a computer, a wearable device, an Internet of things (IoT) device, a laptop computer, a server, a base station, and a device in an automotive vehicle.

Accordingly, it will be appreciated, for example, that an apparatus or any component of an apparatus may be configured to (or made operable to or adapted to) provide functionality as taught herein. This may be achieved, for example: by manufacturing (e.g., fabricating) the apparatus or component so that it will provide the functionality; by programming the apparatus or component so that it will provide the functionality; or through the use of some other suitable implementation technique. As one example, an integrated circuit may be fabricated to provide the requisite functionality. As another example, an integrated circuit may be fabricated to support the requisite functionality and then configured (e.g., via programming) to provide the requisite functionality. As yet another example, a processor circuit may execute code to provide the requisite functionality.

While the foregoing disclosure shows various illustrative aspects, it should be noted that various changes and modifications may be made to the illustrated examples without departing from the scope defined by the appended claims. The present disclosure is not intended to be limited to the specifically illustrated examples alone. For example, unless otherwise noted, the functions, steps, and/or actions of the method claims in accordance with the aspects of the disclosure described herein need not be performed in any particular order. Furthermore, although certain aspects may be described or claimed in the singular, the plural is contemplated unless limitation to the singular is explicitly stated.

What is claimed is:

1. An apparatus comprising:
a semiconductor device having a substrate comprising:
a column comprising a conductive paste that passes through multiple metal layers;
a resin sheath surrounding the column, wherein the resin sheath comprises a dielectric material;
a ground shield surrounding the resin sheath; and
a plurality of sense lines including a first sense line and a second sense line, wherein the first sense line is connected to the column and the second sense line is connected to the ground shield.

2. The apparatus of claim 1, wherein the substrate comprises a cored substrate.

3. The apparatus of claim 1, wherein the substrate comprises a coreless substrate.

4. The apparatus of claim 1, wherein at least a portion of the sense lines are coupled to a Power Management Integrated Circuit (PMIC).

5. The apparatus of claim 1, wherein the column comprising the conductive paste has a diameter of about 100 micrometers.

6. The apparatus of claim 1, wherein the column, the resin sheath, and the ground shield combined occupy an area of about 250 micrometers by about 250 micrometers.

7. The apparatus of claim 1, further comprising:
a die coupled to the semiconductor device.

8. The apparatus of claim 1, wherein the apparatus is selected from the group consisting of: a music player, a video player, an entertainment unit, a navigation device, a communications device, a mobile device, a mobile phone, a smartphone, a personal digital assistant, an access point, a fixed location terminal, a tablet computer, a computer, a wearable device, an Internet of things (IoT) device, a laptop computer, a server, a base station, and a device in an automotive vehicle.

9. A method of fabricating a semiconductor device, the method comprising:
building up a substrate comprising:
forming a column comprising a conductive paste that passes through a plurality of metal layers;
forming a resin sheath that surrounds the column, wherein the resin sheath comprises a dielectric material;
forming a ground shield that surrounds the resin sheath; and
forming a plurality of sense lines including a first sense line and a second sense line, wherein the first sense line is connected to the column and the second sense line is connected to the ground shield.

10. The method of claim 9, wherein the substrate comprises a cored substrate.

11. The method of claim 9, wherein the substrate comprises a coreless substrate.

12. The method of claim 9, wherein at least a portion of the sense lines are coupled to a Power Management Integrated Circuit (PMIC).

13. The method of claim 9, wherein the column comprising the conductive paste has a diameter of about 100 micrometers.

14. The method of claim 9, wherein the column, the resin sheath, and the ground shield combined occupy an area of about 250 micrometers by about 250 micrometers.

15. The method of claim 9, further comprising:
coupling a die to the semiconductor device.

16. The method of claim 9, further comprising including the semiconductor device in an apparatus that is selected from the group consisting of: a music player, a video player, an entertainment unit, a navigation device, a communications device, a mobile device, a mobile phone, a smartphone, a personal digital assistant, an access point, a fixed location terminal, a tablet computer, a computer, a wearable device, an Internet of things (IoT) device, a laptop computer, a server, a base station, and a device in an automotive vehicle.
